(19) United States
(12) Patent Application Publication
(10) Pub. No.: US 2013/0320429 A1
(43) Pub. Date: Dec. 5, 2013

(54) PROCESSES AND STRUCTURES FOR DOPANT PROFILE CONTROL IN EPITAXIAL TRENCH FILL

(71) Applicant: Shawn Thomas, Gilbert, AZ (US)

(72) Inventor: Shawn Thomas, Gilbert, AZ (US)

(73) Assignee: ASM IP HOLDING B.V., Almere (NL)

(21) Appl. No.: 13/484,904

(22) Filed: May 31, 2012

(51) Int. Cl. H01L 21/20; H01L 29/772

(52) U.S. Cl. 257/329; 438/478; 438/479; 257/E21.09; 257/E29.242

(57) ABSTRACT

Methods of depositing epitaxial material using a repeated deposition and etch process. The deposition and etch processes can be repeated until a desired thickness of silicon-containing material is achieved. During the deposition process, a doped silicon film can be deposited. The doped silicon film can be selectively deposited in a trench on a substrate. The trench can have a liner comprising silicon and carbon prior to depositing the doped silicon film. The doped silicon film may also contain germanium. Germanium can promote uniform dopant distribution within the doped silicon film.

### BACKGROUND OF THE INVENTION

1. Field of the Invention

This application relates to methods of epitaxial deposition of silicon-containing materials.

2. Description of the Related Art

Semiconductor processing is typically used in the fabrication of integrated circuits, which entails particularly stringent quality demands, as well as in a variety of other fields. In forming integrated circuits, epitaxial layers are often desired in deep trenches. While non-epitaxial (amorphous or polycrystalline) material can be selectively removed from over the field isolation regions after a “blanket” deposition, it is typically considered more efficient to simultaneously provide chemical vapor deposition (CVD) and etching chemicals, and to tune conditions to result in zero net deposition over insulative regions and net epitaxial deposition over exposed semiconductor windows. This process, known as “selective” epitaxial deposition, takes advantage of slow nucleation of typical semiconductor deposition processes on insulators like silicon oxide or silicon nitride. Such selective epitaxial deposition also takes advantage of the naturally greater susceptibility of amorphous and polycrystalline materials to etchants, as compared to the susceptibility of epitaxial layers to the same etchants.

More recently, cyclical processes have been developed whereby blanket deposition (which may or may not be partially selective) is alternated with selective removal steps. Such cyclical deposition and etch (CDE) sequences have advantages for tailoring the growth of single crystal semiconductor. An example of CDE is disclosed in U.S. Patent Publication No. 2011-0117732, published May 19, 2011.

CDE can be tuned to facilitate filling deep, high aspect ratio trenches (whether or not selective to insulators). However, the fluctuations in precursors tends to cause non-uniformities in the composition of the trench-fill epitaxial material.

### SUMMARY OF THE INVENTION

According to one aspect of the invention, methods for forming a material comprising silicon are provided. The methods generally comprise providing a substrate into a vapor deposition chamber; epitaxially depositing a carbon-containing layer on the substrate in the chamber with a thickness of less than about 1000 Å and epitaxially depositing a silicon-containing layer on the carbon-containing layer within the chamber. Depositing the silicon-containing layer can include depositing a silicon-containing sub-layer including epitaxial material by providing a precursor comprising silicon and providing a dopant precursor followed by etching portions of the silicon-containing sub-layer. The methods can also include alternately repeating depositing the silicon-containing sub-layer and etching portions of the silicon-containing sub-layer in the same chamber until a desired thickness of epitaxial material comprising silicon is deposited. In some embodiments no carbon containing precursor is supplied to the vapor deposition chamber during epitaxially depositing the silicon-containing sub-layers.

According to one aspect of the invention, methods for depositing a film comprising silicon in a trench are provided. The methods can include providing a substrate in a vapor deposition chamber, the substrate comprising a trench; depositing an epitaxial liner comprising carbon in the trench; depositing epitaxial filler comprising silicon and an electrical dopant over the liner in the trench. In some embodiments, no carbon precursor is provided to the vapor deposition chamber during depositing the epitaxial filler.

According to one aspect of the invention, a semiconductor device is provided. The semiconductor device can comprise a substrate including a trench with a bottom and walls and an epitaxial liner comprising carbon and silicon formed on the bottom and walls of the trench. The semiconductor device can also include an epitaxial filler comprising silicon and a dopant with no carbon formed within the trench over the liner. The dopant concentration in the epitaxial material can be substantially uniform across a horizontal cross-section and across a vertical cross section within the trench.

According to one aspect of the invention, a power metal oxide silicon field effect transistor (MOSFET) is provided. The MOSFET can comprise a substrate including a trench with a bottom and walls and an epitaxial filler comprising silicon and a dopant. The epitaxial filler can be a P-doped pillar extending downwardly from a N+ source in the power MOSFET.

### BRIEF DESCRIPTION OF THE DRAWINGS

FIG. 1 is a flow chart illustrating a cyclical epitaxial formation process according to one embodiment of the present application.

FIGS. 2A and 2B show graphs illustrating the flow rate of an etchant, silicon-precursor, germanium precursor and dopant precursor versus time according to embodiments of the present application.

FIG. 3 is a schematic cross-section of a power MOSFET including guard ring trenches epitaxially filled in accordance with an embodiment.

FIG. 4 is a tunneling electron microscope (TEM) image of a trench filled with epitaxial material.

FIG. 5 is a flow chart illustrating an epitaxial formation process to fill a trench or recess according to one embodiment of the present application.

FIG. 6A is a schematic cross section of a trench filled without a barrier for comparison purposes. FIG. 6B is a schematic illustration of the dopant concentration in the trench of FIG. 6A.

FIG. 7A is a schematic cross section of a trench in a semiconductor substrate with an epitaxial barrier liner and an epitaxial filler, in accordance with one embodiment. FIG. 7B is a schematic illustration of the dopant concentration in the trench of FIG. 7A.

### DETAILED DESCRIPTION OF THE PREFERRED EMBODIMENT

Improved methods for depositing doped epitaxial films are disclosed herein. In some embodiments a semiconductor material and a dopant can be deposited having an improved compositional uniformity. In some embodiments a semiconductor material comprising carbon can be deposited prior to depositing additional semiconductor material without carbon. The material comprising carbon can prevent diffusion of the dopant to adjacent areas. In some embodiments, germanium can be added to the additional semiconductor material to improve diffusion of the dopant and promote a uniform distribution of the dopant. In some embodiments the semiconductor and additional semiconductor films can be deposited using a cyclical deposition process, for example in a power MOSFET, with the deposition conditions tuned so that the deposited material fills a trench without voids.

In some embodiments a doped semiconductor and particularly silicon-containing film can be deposited in a recess or trench in a substrate. In some embodiments an epitaxial liner can be deposited on the sides and bottom of the recess or trench prior to depositing an epitaxial doped filler film. Carbon can be included in the thin epitaxial liner as a kind of dopant diffusion barrier. Carbon can inhibit diffusion of the dopant from the filled trench to surrounding areas of the substrate. Methods and apparatuses of the epitaxial liner comprising carbon and doped silicon filler are provided herein. Additionally, carbon can be omitted from the remainder of the epitaxial filler within the trench liner. Furthermore, a small amount of germanium in the filler can promote dopant diffusion and thus dopant concentration uniformity within the confines of the carbon-containing liner.

The term “silicon-containing material,” material comprising silicon, and similar terms are used herein to refer to a broad variety of silicon-containing materials, including without limitation, silicon (including crystalline silicon), doped silicon (e.g. “B:Si”), silicon germanium (“SiGe”), SiGeSn, and doped silicon germanium (e.g. “B:SiGe”). As used herein, “carbon-doped silicon”, “Si:C”, “silicon germanium”, “SiGe,” “carbon-doped silicon germanium”, “SiGe:C”, boron doped silicon germanium, and similar terms refer to materials that contain the indicated chemical elements in various proportions and, optionally, minor amounts of other elements. For example, “silicon germanium” is a material that comprises silicon, germanium and, optionally, other elements, for example, dopants. Shorthand terms such as “Si:C” and “SiGe:C” are not stoichiometric chemical formulas per se and thus are not limited to materials that contain particular ratios of the indicated elements. In addition, the methods taught herein are also applicable to depositing silicon-containing epitaxial material over high aspect ratio features such as trenches, for finFET devices, tri-gates, OMEGA FETs, power MOSFETs, and other devices.

Substrate can refer either to the workpiece upon which deposition is desired, or the surface exposed to one or more deposition gases. For example, in certain embodiments, the substrate is a single crystal silicon wafer, a semiconductor-on-insulator (“SOT”) wafer, or an epitaxial silicon surface over a wafer, a silicon germanium surface over a wafer, or a III-V material deposited upon a wafer. Workpieces are not limited to wafers, but also include glass, plastic, or other substrates employed in semiconductor processing. In some embodiments, the substrate has been patterned to have two or more different types of surfaces, such as both semiconductor and insulator surfaces. Examples of insulator materials include silicon dioxide, including low dielectric constant forms, such as carbon-doped and fluorine-doped oxides of silicon, silicon nitride, metal oxide and metal silicate. In certain embodiments, silicon-containing layers are selectively formed over single crystal semiconductor materials while allowing for minimal or zero growth of material over adjacent insulators. According to some embodiments, any material growth over adjacent insulators may be amorphous or polycrystalline non-epitaxial growth. In other embodiments there may be no exposed insulators at the time of epitaxial deposition.

In certain applications, a patterned substrate has a first surface having a first surface morphology and a second surface having a second surface morphology. Even if surfaces are made from the same elements, the surfaces are considered different if the morphologies or crystallinity of the surfaces are different. Amorphous and crystalline are examples of different morphologies. Polycrystalline morphology is a crystalline structure that consists of a disorderly arrangement of orderly crystals and thus has an intermediate degree of order. The atoms in a polycrystalline material are ordered within each of the crystals, but the crystals themselves lack long range order with respect to one another. Single crystal morphology is a crystalline structure that has a high degree of long range order. Epitaxial films are characterized by an in-plane crystal structure and orientation that is identical to the substrate upon which they are grown, typically single crystal. The atoms in these materials are arranged in a lattice-like structure that persists over relatively long distances on an atomic scale. Amorphous morphology is a non-crystalline structure having a low degree of order because the atoms lack a definite periodic arrangement. Other morphologies include microcrystalline and mixtures of amorphous and crystalline material. “Non-epitaxial” thus encompasses amorphous, polycrystalline, microcrystalline and mixtures of the same. As used herein, “single-crystal” or “epitaxial” are used to describe a predominantly large crystal structure having a tolerable number of faults therein, as is commonly employed for transistor fabrication. The crystallinity of a layer generally falls along a continuum from amorphous to polycrystalline to single-crystal; a crystal structure is often considered single-crystal or epitaxial despite a low density of faults. Specific examples of patterned substrates having two or more different types of surfaces, whether due to different morphologies and/or different materials, include without limitation: single crystal/polycrystalline, single crystal/amorphous, single crystal/dielectric, conductor/dielectric, and semiconductor/dielectric. Methods described herein for depositing silicon-containing films onto patterned substrates having two types of surfaces are also applicable to mixed substrates having three or more different types of surfaces. In other embodiments, a substrate can be “patterned” in the sense of having trenches, formed therein, with or without exposed insulators at the time of epitaxial deposition.

In some embodiments, the deposition process is blanket (i.e., at least some net deposition takes place on all substrate surfaces exposed to the deposition vapors), while in other embodiments where insulator(s) are exposed during the deposition, the deposition process is selective. In a selective deposition, a silicon-source precursor is used with an etchant to deposit material over a semiconductor structure. In some embodiments, a small amount of etching chemicals may be provided during the deposition process such that the deposition can be considered “partially selective,” but nevertheless blanket, since each deposition can still have some net deposition over isolation regions. Accordingly, addition of an etchant with the silicon-source precursor results in deposition that can be completely selective or partially selective. The deposition (whether blanket or selective) is followed by an etch process to remove deposited material from areas of the semiconductor structure. These deposition and etch processes can be alternately repeated in a cyclical process. If the net result of both deposition and etch is zero growth on some surfaces (e.g., insulators), the process can be referred to as selective epitaxial formation, to distinguish selectivity in the deposition phase. An inert carrier gas can be used during the deposition process, the etch process or both.

Methods of epitaxial formation are described that are useful for depositing a variety of doped silicon-containing materials. According to embodiments of the present application, silicon-containing material doped with electrical dopants, particularly boron, and/or germanium can be deposited. In some embodiments, the doped silicon-containing material will be deposited by performing a blanket deposition phase at a relatively high rate or another silicon source and a dopant gas or vapor, alternated with an etch phase that selectively removes non-epitaxial or relatively defective epitaxial semiconductor deposits compared to less defective epitaxial deposits. In other embodiments, the deposition phase may be selective or partially selective. Alternation of deposition and etching phases in a cyclical fashion can permit control of the relative growth in different parts of the recess or trench, e.g., to promote bottom-up filling or otherwise facilitate void-free epitaxial filling of high aspect ratio trenches, vias, or recesses.

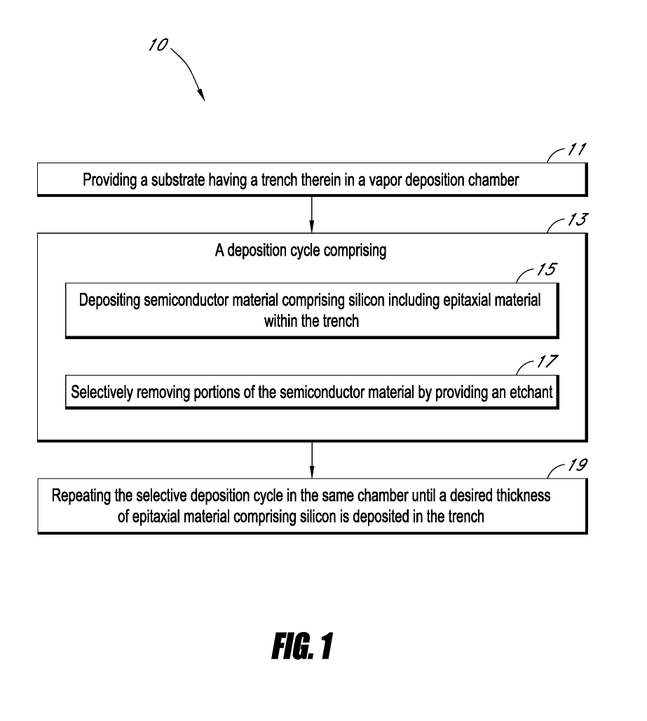

FIG. 1 is a flow chart illustrating an epitaxial formation process 10 according to one embodiment of the present application. A substrate having a trench therein is provided 11 in a vapor deposition chamber. A deposition cycle can then be performed 13. The deposition cycle includes depositing semiconductor material comprising silicon including epitaxial material within the trench by providing 15 a precursor comprising silicon and providing a dopant precursor followed by selectively removing portions of the semiconductor material by providing an etchant 17. The deposition cycle can be repeated 19 in the same chamber until a desired thickness of epitaxial material comprising silicon is deposited in the trench. In some embodiments depositing the silicon-containing layer includes depositing a silicon sub-layer followed by etching portion of the silicon-containing sub-layer.

In some embodiments the epitaxial deposition can be used to deposit material on a planar surface. In some embodiments the epitaxial deposition can be used to deposit material in a recess or trench structure on a substrate, for example a high aspect ratio trench, as noted in FIG. 1.

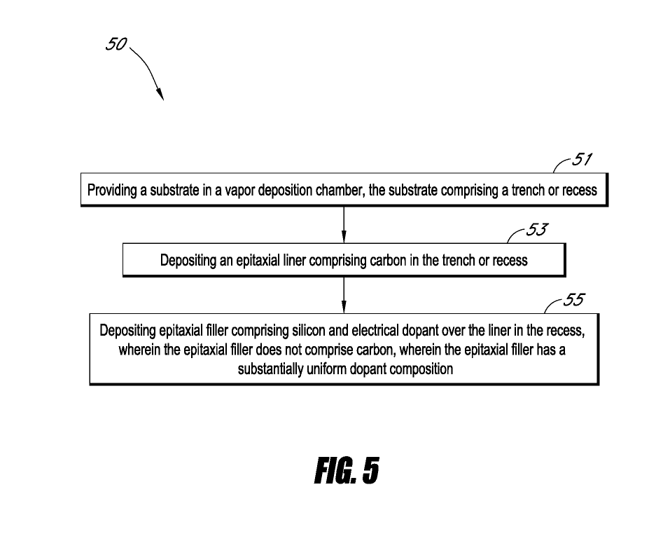

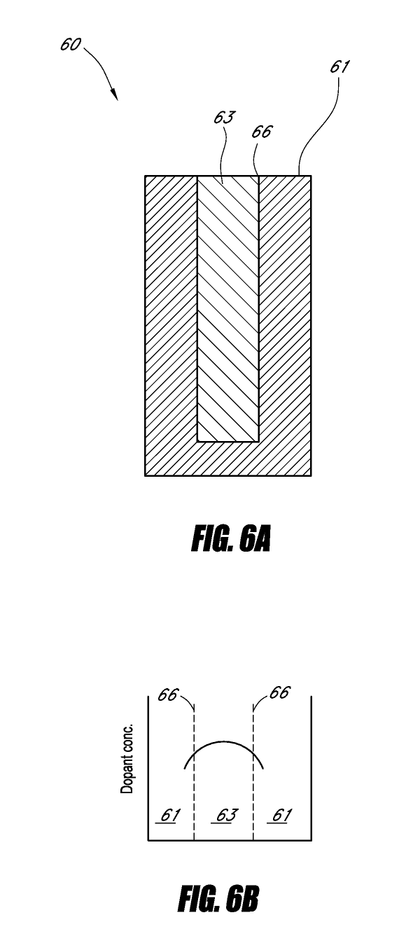

In some embodiments the semiconductor material comprising silicon is deposited on a carbon-containing layer, as will be better understood from the description of FIGS. 5-6B below. In some embodiments the carbon-containing layer is deposited by providing a precursor comprising carbon to the vapor deposition chamber. In some embodiments no carbon precursor is provided to the deposition chamber when depositing the semiconductor material comprising silicon over the carbon-containing layer.

In some embodiments the amount of etchant used in both phases of each cycle is tuned to tailor the profile of deposition remaining from each cycle. The etchant can also be tuned to ensure that little or no deposition occurs on the insulating materials present on the substrate surface, such that the overall process is selective. For embodiments filling high aspect ratio trenches, typically tuning to ensure good filling of the trench would also ensure selectivity if any insulators were exposed to the reactants; however, there need not be any insulators formed on the substrate at the time of deposition.

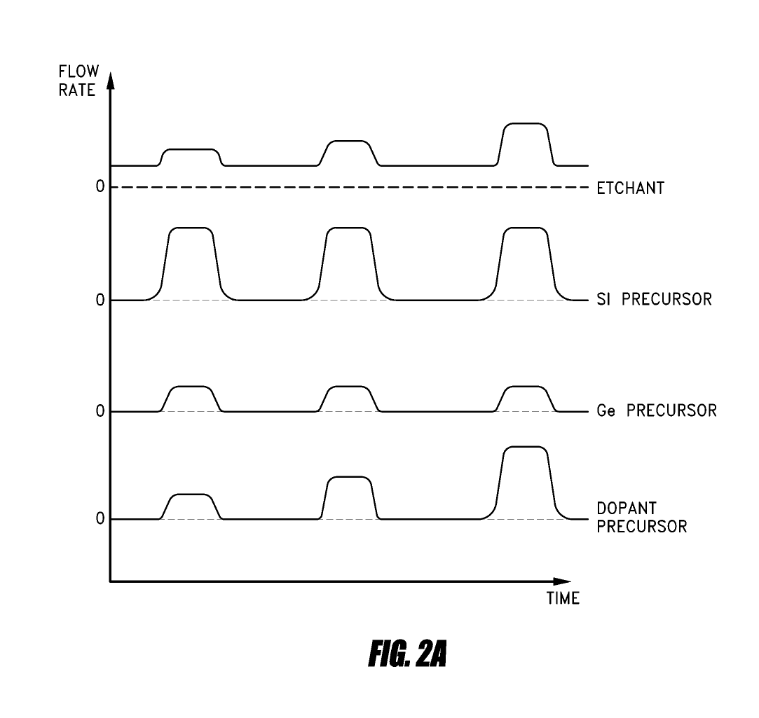

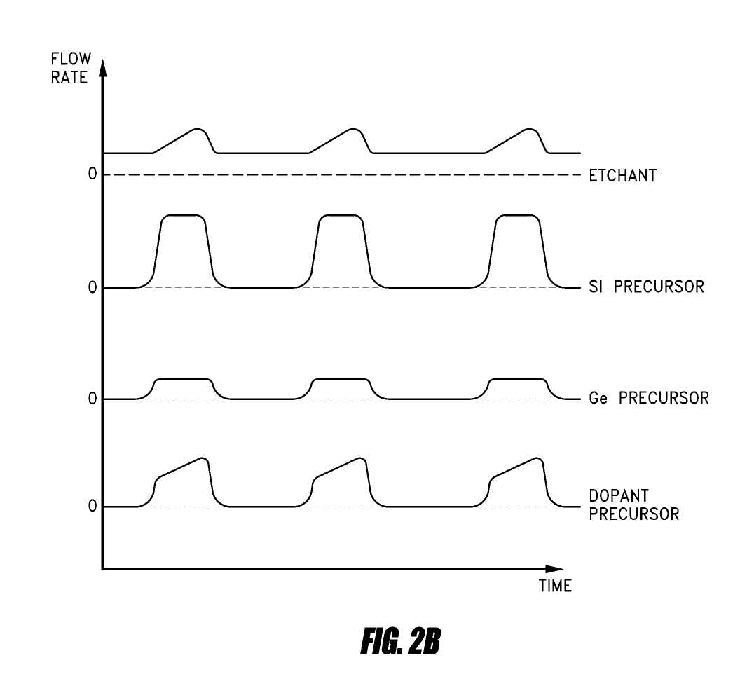

As discussed in more detail below and illustrated in FIGS. 2A and 2B, it may be advantageous to alter the etchant flow in deposition stages from cycle-to-cycle (FIG. 2A) or within a deposition stage (FIG. 2B). Such tuning of etchant flow can facilitate tailoring the profile of the depositions, e.g., to encourage bottom-up filling or otherwise facilitate complete epitaxial filing of a trench or recess. However, such adjustment of etchant flow ratio can cause adjustment in the rate of incorporation of dopants into the growing epitaxial material and thus result in dopant non-uniformity in the deposited material, which can adversely affect device performance. Accordingly, in embodiments, dopant precursor flow rates are adjusted with the etchant flow rates in a manner that homogenizes dopant concentrations in the epitaxial material.

During the silicon-containing material deposition cycle, epitaxial material is deposited along both the base and sidewalls of the trench. In a preferred embodiment, the epitaxial material that is deposited on the base of the recess is boron-doped silicon or boron-doped silicon germanium. Preferably, no carbon source is provided when depositing the epitaxial material.

In some embodiments the epitaxial material can be deposited in a tall and narrow trench, for example a high aspect ratio trench. In some embodiments the trench can have a height (e.g. length from bottom of the trench to the top of the trench or substrate surface) of greater than about 20 μm. In some embodiments the trench can have a height of greater than about 30 μm. In some embodiments the trench can have a height of greater than about 40 μm. In some embodiments the trench can have a height of greater than about 50 μm. In some embodiments the trench can have a height of greater than about 100 μm. In some embodiments the trench can have a width of greater than about 2 μm. In some embodiments the trench can have a width of greater than about 5 μm. In some embodiments the trench can have a width of from about 2 μm to about 5 μm. In some embodiments the side walls of the trench can be substantially parallel. In other embodiments the side walls of the trench can be tapered such that the width at the top of the trench is greater than the width at the bottom of the trench. In some embodiments the filled trench can be part of a power MOSFET.

During the silicon-containing material deposition cycle a precursor comprising silicon can be provided to the reaction space or vapor deposition chamber. The precursor comprising silicon may comprise, but is not limited to, one or more of the following sources, including silane (SiH₄), dichlorosilane or DCS (SiCl₂H₂), disilane (Si₂H₆), monochlorodisilane (MCDS), dichlorodisilane (DCDS), trisilane (Si₃H₈), or 2,2-dichlorotrisilane. In some embodiments, the precursor comprising silicon can be introduced along with a germanium source, an electrical dopant source, or combinations thereof. In embodiments in which a precursor comprising silicon is introduced with a germanium source, a layer of Ge-doped silicon may be deposited on the substrate. In embodiments in which a precursor comprising silicon is introduced with a germanium source and a dopant, a layer of Ge-doped silicon may be deposited on the substrate recess. In some embodiments an etchant is also provided with the precursor comprising silicon.

In some embodiments a p-type or n-type electrical dopant may be added to the reaction space with the precursor comprising silicon to form the epitaxial layer. In some embodiments an electrical dopant comprising boron is used. Typical p-type dopant precursors include diborane (B₂H₆) and boron trichloride (BCl₃) for boron doping. Other p-type dopants for Si include Al, Ga, In, and any metal to the left of Si in the Mendeleev table of elements. Such electrical dopant precursors are useful for the preparation of films as described below, preferably boron-doped silicon, and boron- and Ge-doped silicon, films and alloys.

In some embodiments a n-type electrical dopant may be added to the reaction space with the precursor comprising silicon to form the epitaxial layer. In some embodiments an electrical dopant comprising phosphorus is used. Dopants comprising phosphorus include phosphine (PH₃). Such electrical dopant precursors are useful for the preparation of films as described below, preferably phosphine-doped silicon, and phosphine- and Ge-doped silicon, films and alloys.

In some embodiments using a single wafer chamber, the electrical dopant source (which may be diluted, for example, to 1% in H₂ or He) may be introduced at a flow rate between 50 sccm and 1000 sccm, more preferably between 100 sccm and 300 sccm. For example, in one embodiment, diborane or boron trichloride diluted to 1% in He can be introduced with a silicon source precursor during a deposition phase at a flow rate between 5 and 500 sccm, resulting in the epitaxial growth of a boron-doped silicon film.

In some embodiments, a germanium source is provided with the silicon and electrical dopant source. The germanium source can include monogermane (GeH₄) or digermane (Ge₂H₆). The Ge precursors may be metallorganic. In some embodiments using a single wafer chamber, the germanium source may flow at a rate between 10 and 500 sccm, more preferably between 50 and 200 sccm. In some embodiments the germanium source can also be provided with the etchant.

In some embodiments the germanium source is provided with a flow rate to achieve a desired germanium composition in the doped silicon epitaxial material. In some embodiments the germanium concentration in the epitaxial material is from about 5 atomic % to about 8 atomic %. Germanium can facilitate the diffusion of certain p-type dopants, for example boron. Thus, the use of germanium in the epitaxial filler can promote the diffusion of boron and facilitate the formation of an epitaxial film with a substantially uniform composition of boron across a vertical cross section of the film and also across a horizontal cross section of the film.

In some embodiments the deposition conditions are tuned such that a high quality epitaxial material is deposited to fill a trench with few voids or substantially no voids.

In some embodiments each cycle, including deposition phase and etch phase, achieves net growth on both walls and the bottom of the recess. The epitaxial growth rate on each of the walls and bottom of the recess can be about at least about 200 nm per cycle, at least about 300 nm per cycle, and in some cases greater than about 500 nm per cycle. In some embodiments the trench can be filled with epitaxial material in about 4 to about 5 cycles. In some embodiments the trench can have a width of about 4 to about 5 microns.

Various etchants can be provided during the silicon-containing layer deposition cycle. In some embodiments, the etchant may be comprised of a halide, such as a fluorine-, chlorine-, bromine- or iodine -containing vapor compound. The etchant may have a flow rate between 5 and 2000 sccm. For example, in one embodiment, the etchant is comprised of a chlorine source, such as HCl or Cl₂ that flows continuously between 5 and 1000 sccm. Depending on the etchant used, the preferred flow rate may vary. For example, with HCl etchant, the preferred flow rate is between 200 and 2000 sccm. With Cl₂ etchant, the preferred flow rate is between 50 and 200 sccm for a single wafer epitaxial CVD reaction. In some embodiments, the etch chemistry may also contain a germanium source, such as monogermane (GeH₄) or digermane (Ge₂H₆). The Ge precursors may be metalorganic. In some embodiments, the germanium source may flow at a rate between 10 and 500 sccm, more preferably between 50 and 200 sccm. For example, in one embodiment, a monogermane (GeH₄ diluted to 10%) source can be provided during the etchant flow at a flow rate of between 50 and 200 sccm.

In some embodiments the etchant is provided continuously during the deposition cycle. In other embodiments the etchant is provided cyclically during the deposition cycle.

The flow rate of the etchant can affect the incorporation of dopant in the epitaxial silicon-containing material. For example, increasing the etchant flow rate can decrease the dopant incorporation in the deposited epitaxial silicon-containing material. In order to maintain a constant incorporation of dopant in the deposited epitaxial silicon-containing material the dopant flow rate can also be increased when the etchant flow rate increases. In some embodiments the flow rate of the etchant can be increased in comparison to the flow rate of etchant from the previous silicon-containing layer deposition cycle. FIG. 2A shows a graph illustrating the flow rate of an etchant, silicon-precursor, germanium precursor and dopant precursor versus time according to embodiments of the present application. FIG. 2A shows a process with the etchant flow rate and dopant precursor flow rates increasing step-wise in comparison to the flow rates used in the previous cycle. In some embodiments the flow rate of the etchant can be selected based on the flow rate of dopant to result in a substantially uniform dopant concentration in the deposited silicon doped film.

In some embodiments the flow rate of the etchant can be increased during a single silicon-containing layer deposition cycle. FIG. 2B shows a graph illustrating the flow rate of an etchant, silicon-precursor, germanium precursor and dopant precursor versus time according to embodiments of the present application. FIG. 2B shows a process with the etchant and dopant flow rates that increase with each cycle. It will be understood that etchant variation during CDE can take many forms, and that compensating changes in electrical dopant flow to maintain dopant uniformity can be initially determined by theory and fine-tuned by trial-and-error.

In some embodiments, one or more etchants may be introduced intermittently throughout the process, while at least one other etchant is flowing at all times throughout the silicon-containing layer deposition process. For example, according to one embodiment, a continuous etchant flow may include introducing Cl₂ as an etchant throughout the silicon-containing layer deposition process, while introducing HCl and/or germane as a second etching agent periodically during the Cl₂ flow. Providing an etchant during a periodic deposition process, while continuously flowing etchant between deposition phases can provide a number of benefits. For example, growth rates during the deposition can be tuned for one or more purposes (step coverage, dopant incorporation, throughput speed, selectivity, etc.) independently of the others, and the intervening etch phases can accomplish others of those goals.

In one embodiment, a single vapor-phase etchant is introduced, while in other embodiments, two, three, or more vapor-phase etchants may be used throughout the silicon-containing layer deposition process. These etchants may include halide gases, such as Cl₂ and HCl. Other examples include Br₂, HBr, and HI.

In some embodiments the substrate processing temperature is greater than about 800° C. In some embodiments the substrate processing temperature is greater than about 900° C. The temperature can be selected based on the reactivity of the precursors and etch rates of the etchant. For higher temperature processing HCl can be used as the etchant. For lower temperature processing Cl₂ can be used as the etchant, for example temperatures below about 600° C.

In some embodiments the reaction chamber has a pressure between 10 and 760 Torr, more preferably between 10 and 200 Torr. In some embodiments, the temperature and/or pressure may fluctuate during the cyclical silicon-containing layer deposition process. For example, in one embodiment, pressure may vary during the cyclical silicon-containing layer deposition process. In other embodiments, it is typically more efficient to select conditions under which temperature or the pressure will remain constant during the process. In a preferred embodiment, both the temperature and the pressure will remain constant such that the cyclical silicon-containing layer deposition and etch process takes place under isothermal and isobaric conditions, which helps to ensure a high throughput.

In one embodiment, an etchant will be introduced at the same time as the introduction of a first pulse of a deposition precursor. In another embodiment, an etchant will be introduced prior to the introduction of a first pulse of a deposition precursor. When the etchant is introduced prior to the introduction of a first pulse of a deposition precursor, the etchant may be introduced between 1 and 20 seconds, more preferably, between 3 and 10 seconds after wafer temperature stabilization and before deposition precursors are started. An etchant (e.g., HCl) according to one embodiment of the present application for a 300-mm, single-wafer system, may have a flow rate between 2 and 2000 sccm, more preferably between 5 and 600 sccm.

An etchant may be introduced into a processing chamber with a reducing carrier gas such as H₂, or an inert carrier gas such as He, Ar or N₂. The carrier gas will be introduced into the chamber with the etchant at a flow rate of between 1 and 30 slm, more preferably between 2 and 20 slm. The carrier gas, like the etchant, may be introduced prior to the introduction of the first pulse of deposition vapor. In one example, both an etchant, such as Cl₂ or HCl, and a carrier gas, such as H₂, He or N₂, are introduced 5 seconds before introducing a first pulse of a deposition vapor.

Depending on the number of deposition phases needed to achieve a desired epitaxial thickness, the duration of the total epitaxial process may last for a total duration between 120 and 900 seconds (or 2 to 15 minutes). In some embodiments the substrate can be heat treated or annealed after epitaxially depositing the silicon containing material.

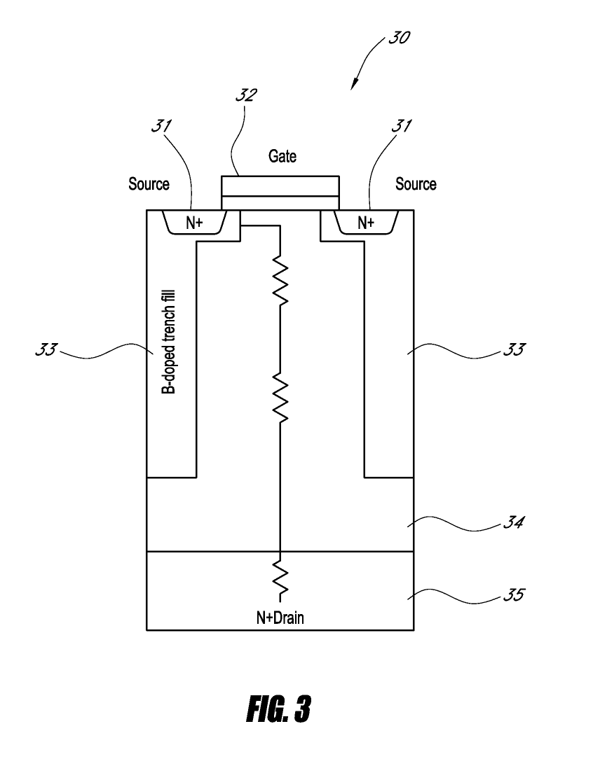

FIG. 3 is a schematic illustration of a portion of a transistor structure in accordance with one embodiment. Because such vertical transitions are useful for power management applications dealing with high voltages and currents, they are often referred to as power MOSFETS. The illustrated, transistor 30 has an N+ source 31, a gate 32, an N-doped channel region 34, and an N+ drain 35. The processes disclosed herein can be used, e.g., to deposit an epitaxial boron-doped silicon filling a trench to define a doped guard ring or line 33. The trench fill 33 is narrow so it is preferably not strained relative to the surrounding materials in the transistor. Such deep, narrow and relatively heavily doped structures as the guard ring or line 33 are difficult to uniformly dope by traditional techniques, such as diffusion doping or implantations. Fairchild Semiconductor produces such deep P-doped pillars by multiple epitaxial layering steps with intervening masked doping steps, which is a complicated and expensive process and does not produce well-defined, straight-wall pillars. Accordingly, filling a trench by CDE is employed in accordance with embodiments taught herein.

The transistor 30 arrangement can have a high breakdown voltage. The thickness (e.g. in the direction between gate 32 and N+ drain 35) of the transistor 30 can define the breakdown voltage.

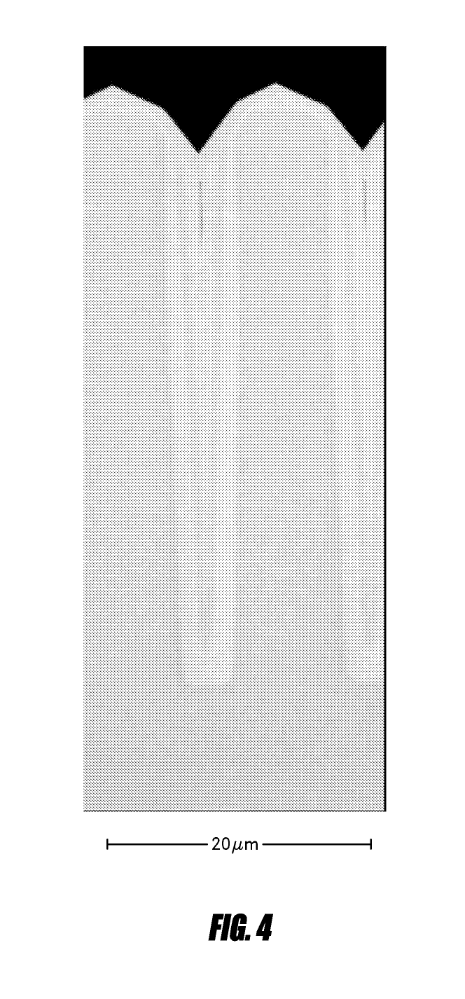

FIG. 4 is a tunneling electron microscope (TEM) image of a deep and narrow trench filled with epitaxial material . FIG. 4 shows a high aspect ratio trench filled with epitaxial material. The illustrated trench shows high quality doped silicon deposited in the trench. The filled trench has a height of about 50 μm, a width at the bottom of about 5 μm, and a width at the top of the trench of about 8 μm.

In some embodiments an epitaxial material comprising carbon can be deposited prior to epitaxially filling the remainder of the trench. In some embodiments the epitaxial material comprising carbon comprises carbon and silicon. In some embodiments the carbon content can be from about 0.3 atomic % to about 0.5 atomic %. Carbon can prevent the diffusion of dopants, such as boron, from diffusing outside of the area inside the trench during deposition and any subsequent processing steps. In some embodiments the epitaxial material comprising carbon can be used to line a trench.

FIG. 5 is a flow chart illustrating an epitaxial formation process 50 according to one embodiment of the present application. A substrate is provided 51 in a vapor deposition chamber, the substrate comprising a trench or recess. An epitaxial liner comprising carbon is deposited 53 in the trench or recess. An epitaxial filler comprising silicon and electrical dopant is deposited over the liner in the recess 55, wherein the epitaxial filler does not comprise carbon, wherein the epitaxial filler has a substantially uniform dopant composition.

In some embodiments a carbon source vapor may be provided during the epitaxial liner deposition 53 to form an epitaxial liner comprising carbon in a recess on a substrate. The carbon source may comprise silylalkanes such as monosilylmethane, disilylmethane, trisylmethane and tetrasilylmethane, and/or alkylsilanes such as monomethyl silane (MMS) and dimethyl silane. In some embodiments, a carbon source comprises H₃ Si—CH₂—SiH₂—CH₃ (1,3-disilabutane). In some embodiments using a single wafer reaction chamber, the carbon source may be introduced at a flow rate between 25 and 500 sccm, more preferably between 50 and 200 sccm. For example, in addition to a silicon-source vapor source, monomethyl silane (MMS) may be introduced at a flow rate between 50 and 200 sccm such that carbon atoms are incorporated into the deposited epitaxial material, thus forming carbon-doped silicon epitaxial liner films in the recesses. Such carbon doped silicon films may have both substitutional and interstitial carbon. In some embodiments, the concentration of carbon in the epitaxial liner is from about 0.3 to about 0.5%. In a preferred embodiment, a precursor comprising silicon and monomethyl silane will be added to deposit the epitaxial liner. In some embodiments, monomethyl silane is used to deposit the epitaxial liner. In some embodiments a precursor comprising silicon or silicon source can also be provided during the deposition of the carbon trench liner. In one embodiment, a germanium source and an electrical dopant source, such as boron, are not provided when depositing the epitaxial liner.

The thickness of the epitaxial carbon-containing trench liner can be selected based on the deposition temperatures and temperatures used for subsequent processing of the substrates. Generally, dopant diffusion increases with temperature thus a thicker epitaxial carbon-containing liner can be used when higher deposition and processing temperatures are used in order to prevent or reduce diffusion of the dopant from outside of the trench. In some embodiments the epitaxial carbon-containing trench liner is deposited to a thickness of about 1000 Å or less. For deposition temperatures of about 900° C. or greater the thickness of the epitaxial carbon-containing trench liner is at least about 300 Å. In some embodiments the thickness of the epitaxial carbon-containing trench liner is at least about 500 Å. For lower processing temperatures, such as temperatures of below about 600° C. (e.g. for epitaxial filler deposition processes using trisilane and Cl₂), a thickness of less than 100 Å may be suitable.

The epitaxial filler deposition 55 can include no carbon but include small amounts of germanium, e.g. about 5 to about 8% Ge, to promote diffusion of electrical dopant, particularly boron, within the epitaxial filler.

The carbon in the epitaxial liner can be both interstitial and substitutional. Typically, the carbon does not diffuse significantly during subsequent deposition and processing of the substrate. In some embodiments the concentration of carbon in the epitaxial trench liner and the concentration of germanium in the epitaxial filler and their relative thicknesses can be selected such that their stresses offset, resulting in little or no strain in the trench.

FIG. 6A is a schematic cross section of a trench epitaxially filled without a barrier liner. The substrate 60 has a single-crystal material 61 surrounding the trench-fill material 63. The material 61 contacts the trench-fill material 63 at interface 66. FIG. 6B is a schematic illustration of the dopant concentration in the trench of FIG. 6A. Without an epitaxial liner comprising carbon the boron or other dopant in the trench material 53 tends to diffuse into the surrounding material 61 as shown in FIG. 6B. The dopant profile of substrate 60 would vary across the horizontal cross section of the trench-fill material 63 with a maximum concentration in the middle of the trench-fill material 63 with the dopant concentration decreasing away from the middle of the trench-fill material 53 because of diffusion of the dopant out of the trench.

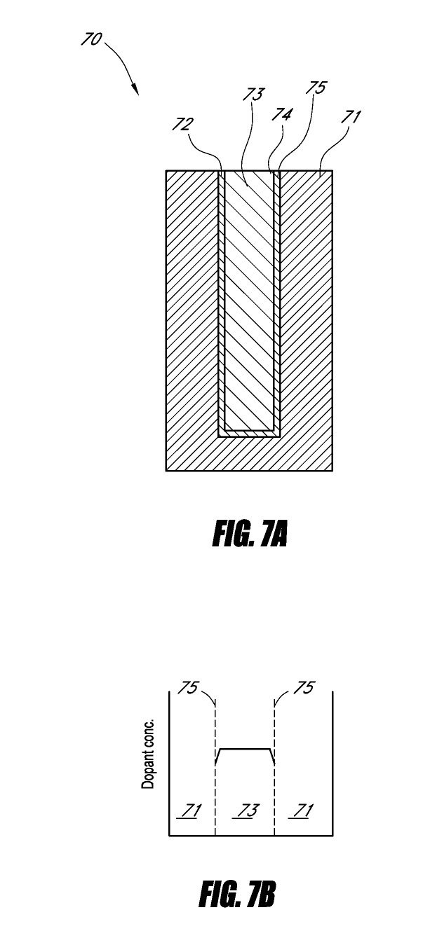

FIG. 7A is a schematic cross section of a trench in accordance with one embodiment. FIG. 7A shows a substrate 70 with a single-crystal material 71 surrounding a trench filled with epitaxial material 72, 73. The single-crystal material 71 in which the trench has been etched can be bulk silicon wafer material or a thick epitaxial layer. The trench fill material includes an epitaxial liner 72 and an epitaxial filler 73. The epitaxial liner 72 can be a silicon-containing material including an amount of carbon effective to confine dopants from the epitaxial filler 73 to the trench. The epitaxial filler 73 can be a silicon-containing material including an electrical dopant, particularly the P-type dopant boron. The epitaxial filler 73 can also include an amount of germanium effective to allow the electrical dopant to diffuse evenly throughout the trench without creating undue stress. Each of the epitaxial liner 72 and the epitaxial filler 73 can be deposited by CDE and the epitaxial filler 73 in particular can be deposited with ramped etchant flow as disclosed above with respect to FIGS. 1-2B. The epitaxial liner 72 has an interface 74 with the epitaxial filler 73 and an interface 75 with surrounding substrate material 71. FIG. 7B is a schematic illustration of the dopant concentration (e.g. boron) in the trench of FIG. 7A. The dotted lines on the dopant concentration illustration correspond to the interface 75. FIG. 7B shows a substantially uniform boron dopant concentration across a horizontal cross section of the epitaxial filler 73. The boron concentration drops sharply at the interface 74 with the epitaxial liner comprising carbon 72.

Prior art methods, such as multiple deposition of blanket epitaxial layers with intervening masked blanket doping steps, do not result in a material with the dopant profile illustrated in FIG. 7B because, both no sharp trench profile exists and because the dopant can readily diffuse into surrounding areas. The methods and apparatuses disclosed herein also involve fewer processing steps and fewer transports among chambers. Furthermore, more uniform and confined dopant profiles can produce devices with improved electrical properties.

The relative dopant concentration can be measured by secondary ion mass spectrometry (SIMS). In some embodiments the dopant concentration in the epitaxial trench/filler material is substantially uniform across a horizontal cross-section and across a vertical cross section. In some embodiments the P-type dopant concentration at the inner edge of the liner is greater than about 100 times the P-type dopant concentration about 80 Å outside the trench. In some embodiments the concentration of dopant in the epitaxial material at the walls of the recess is significantly greater than the dopant concentration in the areas surrounding the recess. In some embodiments the dopant is substantially confined within the recess.

The epitaxially lined and filled trench as described above can provide a doped pillar surrounding and extending downward from the source region of a power MOSFET, such as the guard ring or line 33 of FIG. 3. In contrast to the SuperFET™ design of Fairchild Semiconductor, the guard ring or line has the shape of a filled trench with straight sidewalls and confined P-type dopant.

In some embodiments, a CVD chamber is provided herein to perform any of the deposition methods disclosed herein. The CVD chamber can include gas sources for any of the process gases taught herein. The CVD chamber can include a process controller with a memory programmed to perform the methods taught herein.

### EXAMPLE 1

A substrate is first provided with a trench having a width of 4-5 μm and a height of about 50 μm. An epitaxial carbon and silicon trench liner is first deposited using MMS. Boron and germanium sources are not provided during deposition of the trench liner. The liner is deposited to a thickness of about 1000 Å over the walls and bottom of the recess.

The trench is then filled by deposition of a boron and germanium doped silicon film using CDE. The boron source is diborane, the germanium source is germane (GeH₄), and dichlorosilane is used as the silicon source. HCl is provided continuously during the cycle, but not at a constant rate. In each cycle, the boron, silicon, and germanium sources are first provided with the HCl followed by just providing HCl. The flow rates of HCl and diborane are both increased in each successive cycle such that the boron concentration in the deposited film is substantially the same as the concentration deposited in the previous cycle. The boron doped silicon germanium trench material is deposited with a substantially constant dopant composition across horizontal and vertical cross sections of the trench. The trench can be filled after about 5 cycles.

It will be apparent to those skilled in the art that various modifications and variations can be made in the present invention without departing from the scope or spirit of the invention. Thus, it is intended that the present invention cover the modifications and variations of this invention provided that they come within the scope of the appended claims or their equivalents.

1. A method for forming material comprising silicon, comprising:
providing a substrate into a vapor deposition chamber;
epitaxially depositing a carbon-containing layer on the substrate in the chamber with a thickness of less than about 1000 Å; and
epitaxially depositing a silicon-containing layer on the carbon-containing layer within the chamber, wherein depositing the silicon-containing layer comprises:
depositing a silicon-containing sub-layer including epitaxial material by providing a precursor comprising silicon and providing a dopant precursor;
etching portions of the silicon-containing sub-layer; and
alternately repeating depositing the silicon-containing sub-layer and etching portions of the silicon-containing sub-layer in the same chamber until a desired thickness of epitaxial material comprising silicon is deposited, wherein no carbon containing precursor is supplied to the vapor deposition chamber during epitaxially depositing the silicon-containing sub-layers.

2. The method of claim 1, wherein alternately repeating includes increasing a flow rate of dopant precursor and increasing a flow rate of etchant in a second cycle relative to a preceding first cycle.

3. The method of claim 1, wherein epitaxially depositing the silicon-containing layer comprises providing a germanium precursor.

4. The method of claim 1, wherein the substrate comprises a recess, wherein the epitaxial material comprising silicon is deposited in the recess during epitaxially depositing the silicon-containing layer.

5. The method of claim 4, wherein the carbon-containing layer forms a liner in the interior of the recess prior to epitaxially depositing the silicon-containing layer.

6. The method of claim 5, wherein the liner comprises silicon and carbon or silicon, carbon, and a dopant, wherein no germanium precursor is provided during deposition of the liner.

7. The method of claim 6, further comprising providing a precursor comprising germanium after forming the liner during epitaxially depositing the silicon-containing layer to deposit a film comprising silicon, germanium, and dopant.

8. The method of claim 1, wherein depositing the silicon-containing sub-layer comprises increasing the flow rate of dopant precursor and increasing the flow rate of etchant in at least one cycle.

9. The method of claim 1, wherein the etchant is additionally provided during depositing the silicon-containing sub-layer.

10. The method of claim 1, wherein the etchant comprises one of HCl, Cl₂, or HBr.

11. The method of claim 1, wherein the precursor comprising silicon is one or more of silane, disilane, trisilane, dichlorosilane, and trichlorosilane.

12. The method of claim 1, wherein the dopant precursor comprises boron.

13. The method of claim 12, wherein the dopant precursor is B₂H₆ or BCl₃.

14. The method of claim 1, further comprising provided a carrier gas during depositing and etching.

15. The method of claim 1, further comprising providing a precursor comprising germanium during depositing the silicon-containing sub-layer.

16. The method of claim 15, wherein the precursor comprising germanium is monogermane (GeH₄).

17. The method of claim 1, further comprising heat treating the substrate after depositing the material comprising silicon.

18. The method of claim 1, wherein the substrate is used to form a power MOSFET.

19. A method for depositing a film comprising silicon in a trench, comprising:
providing a substrate in a vapor deposition chamber, the substrate comprising a trench;
depositing an epitaxial liner comprising carbon in the trench;
depositing epitaxial filler comprising silicon and an electrical dopant over the liner in the trench, wherein during depositing the epitaxial filler no carbon precursor is provided to the vapor deposition chamber.

20. The method of claim 19, wherein the liner comprises silicon and carbon and is deposited by providing a precursor comprising silicon and a precursor comprising carbon.

21. The method of claim 20, wherein the precursor comprising silicon is one or more of silane, disilane, trisilane, dichlorosilane, and trichlorosilane.

22. The method of claim 20, wherein the precursor comprising carbon is one or more of monosilylmethane, disilylmethane, trisylmethane and tetrasilylmethane, and/or alkylsilanes.

23. The method of claim 19, wherein depositing the epitaxial filler is selective relative to exposed insulators.

24. The method of claim 23, wherein depositing the epitaxial filler is a cyclical deposition and etch.

25. The method of claim 19, wherein the dopant is boron.

26. The method of claim 19, wherein the epitaxial filler comprises germanium.

27. The method of claim 19, wherein during depositing the epitaxial liner a precursor comprising germanium is not provided.

28. A semiconductor device comprising:
a substrate including a trench with a bottom and walls; and
an epitaxial liner comprising carbon and silicon formed on the bottom and walls of the trench; and
an epitaxial filler comprising silicon and a dopant with no carbon formed within the trench over the liner, wherein a dopant concentration in the epitaxial filler is substantially uniform across a horizontal cross-section and across a vertical cross section within the trench.

29. The semiconductor device of claim 28, wherein the dopant concentration at the edge of the epitaxial liner is greater than about 100 times the dopant concentration of the epitaxial liner at about 80 Å from an interface of the epitaxial liner and epitaxial filler.

30. The semiconductor device of claim 28, wherein the concentration of dopant in the epitaxial filler at the walls of the recess is significantly greater than the dopant concentration in the areas surrounding the trench.

31. The semiconductor device of claim 28, wherein the epitaxial liner has a carbon concentration of between about 0.3 atomic % to about 0.5 atomic %.

32. The semiconductor device of claim 28, wherein the epitaxial liner has a thickness of about 1000 Å or less.

33. The semiconductor device of claim 28, wherein the dopant is substantially confined within the trench.

34. The semiconductor device of claim 28, wherein the epitaxial filler further comprises germanium.

35. The semiconductor device of claim 34, wherein the epitaxial filler comprises about 5 to about 8 atomic % germanium.

36. The semiconductor device of claim 28, wherein the dopant is boron.

37. The semiconductor device of claim 28, wherein the semiconductor device is part of a vertical power MOSFET.

38. The semiconductor device of claim 37, wherein the trench fill is part of a P-doped pillar extending downwardly from a N+ source in the power MOSFET.

39. A power metal oxide silicon field effect transistor (MOSFET), comprising:
a substrate including a trench with a bottom and walls; and
an epitaxial filler comprising silicon and a dopant, wherein the epitaxial filler is a P-doped pillar extending downwardly from a N+ source in the power MOSFET.

40. The device of claim 39, further comprising an epitaxial liner comprising carbon and silicon formed on the bottom and walls of the trench, wherein the epitaxial filler is formed over the liner in the trench without carbon.

41. The device of claim 40, and wherein a dopant concentration in the epitaxial filler is substantially uniform across a horizontal cross-section and across a vertical cross section within the trench
